(19) United States
(12) Patent Application Publication
(10) Pub. No.: US 2011/0171765 A1
(43) Pub. Date: Jul. 14, 2011

(54) MULTI-FIELD ARRANGING METHOD OF LED CHIPS UNDER SINGLE LENS

(75) Inventors: Chih-Ming Wang, Hsinchu County (TW); I-Lin Ho, Hsinchu County (TW); Shih-Yi Wen, Hsinchu County (TW); Po-Ming Tseng, Hsinchu County (TW); Jiun-Min Lin, Hsinchu County (TW)

(73) Assignee: Helio Optoelectronics Corporation, Zhudong Town, Hsinchu County (TW)

(21) Appl. No.: 13/057,183

(22) PCT Filed: Sep. 23, 2008
(86) PCT No.: PCT/CN08/01641

§ 371 Date: Feb. 2, 2011

(51) Int. Cl. H01L 33/00

(52) U.S. Cl. 438/29; 257/E33.056

(57) ABSTRACT

A multi-field arranging method of LED chips under a single lens includes the steps of: setting a first concentric circle on a bottom of a hemispherical lens, wherein the first concentric circle is centered at an axis of the hemispherical lens; and equidistantly arranging at least one first color chip, at least one second color chip and at least one third color chip on the first concentric circle in sequence. The present invention allows the color chips to present symmetrical light patterns through the hemispherical lens, thereby obtaining a light field with evener color mixture.

### CROSS-REFERENCE TO RELATED APPLICATIONS

This application is a 35 USC 371 application of PCT/CN2008/001641 filed on Sep. 23, 2008, published as Pub. No. WO2010/034133. The content of the specification is incorporated herein by reference.

### BACKGROUND OF THE INVENTION

1. Technical Field

The present invention relates to LED arranging methods, and more particularly, to a multi-field arranging method of LED chips under a single lens applicable to color mixture of multiple LED chips.

2. Description of Related Art

FIG. 1 is a diagram showing light intensity profiles through a conventional hemispherical lens 10. FIG. 2 is another diagram showing light intensity profiles through the conventional hemispherical lens 10. FIG. 3 is a diagram showing light intensity profiles through a conventional planar lens.

FIG. 1 and FIG. 2 are the two diagrams are derived from measuring the light intensity profiles of LED chips of different colors from two different viewpoints through the conventional hemispherical lens 10. According to the diagrams, it is found that since the hemispherical lens 10 has its axis 11 inconsistent with the optical axis of any of the colored LEDs, the resultant light patterns of all the LEDs are asymmetric and varied with viewpoints.

Referring to FIG. 3, while the planar lens gives symmetrical light patterns, most of the emitted light is reflected by the planar lens, causing the overall light extraction efficiency reduced by half as compared with that through the hemispherical lens 10.

FIG. 4A is a schematic drawing illustrating LED chips of three colors arranged under the conventional hemispherical lens 10. FIG. 4B shows the light pattern of the red LED chip under the conventional hemispherical lens 10. FIG. 4C shows the light pattern of the green LED chip under the conventional hemispherical lens 10. FIG. 4D shows the light pattern of the blue LED chip under the conventional hemispherical lens 10.

Referring to FIG. 4A, subject to the relative locations of the LED chips of different colors in the same space and differences between the axis 11 of the hemispherical lens 10 and the optical axis of each of the LED chips, the light patterns of the red LED chip, the green LED chip, and the blue LED chip under the hemispherical lens 10 are as shown in FIG. 4B, FIG. 4C, and FIG. 4D, respectively, all being asymmetric. Thus, polarized light is generated and causes poor color mixture at the peripheral portion of the hemispherical lens 10.

This proves that the existing technology for arranging LED chips under a hemispherical lens still fails to present light patterns that are flawless and convenient to practical applications and needs to be improved. For remedying these problems, the related manufacturers have long spent every effort to develop solutions, yet a suitable design is still absent. Hence, an efficacious multi-field arranging method of LED chips under single lens is exactly the target the industry is seeking for.

In view of the defective light patterns of the existing configurations of LED chips under a hemispherical lens, the inventor of the present invention has, with his years of abundant experience, an professionalism in designing and producing LED products, applied relevant theories to actively research and innovate in expectation to create a novel multi-field arranging method of LED chips under single lens that improve light patterns and is more applicable. After repeated researches, designs, tests and modifications, the present invention of practical value is herein presented.

### SUMMARY OF THE INVENTION

One objective of the present invention is to overcome the defects of the light patterns produced by the existing configurations of LED chips under a hemispherical lens, and to provide a new multi-field arranging method of LED chips under a single lens, wherein the technical issue to be addressed is to make each of the LED chips of different colors under the hemispherical lens present a symmetrical light pattern, so as to allow even color mixture, thus being more practical.

Another objective of the present invention is to provide a new multi-field arranging method of LED chips under a single lens, wherein the technical issue to be addressed is to such arrange the LED chips of various colors at a bottom of the single lens that a light pattern formed by mixture of the light of the LED chips is symmetrical from any viewpoint, thereby improving color mixture at the peripheral portion of the single lens, thus being more practical.

Still another objective of the present invention is to provide a new multi-field arranging method of LED chips under a single lens, wherein the technical issue to be addressed is to arrange the LED chips into concentric circles, so as to maximize the density of the LED chips and thereby downsize the overall configuration, thus being more practical.

To achieve the objectives and to address the technical issues of the present invention, the following technical scheme is adopted. According to the present invention, a multi-field arranging method of LED chips under a single lens comprises the steps of: setting a first concentric circle on a bottom of a hemispherical lens wherein the first concentric circle is centered at an axis of the hemispherical lens; and equidistantly arranging at least one first color chip, at least one second color chip, and at least one third color chip on the first concentric circle in sequence.

To further achieve the objectives and to further address the technical issues of the present invention, the following technical measures may be implemented.

In the foregoing multi-field arranging method, the first color chip, the second color chip, and the third color chip are a red chip, a green chip, and a blue chip, respectively.

In the foregoing multi-field arranging method, the color chips are arranged in an order of red, green, and blue.

In the foregoing multi-field arranging method, there is one said first color chip, two said second color chips, and one said third color chip.

In the foregoing multi-field arranging method, the color chips are arranged in an order of red, green, green, and blue.

In the foregoing multi-field arranging method, each of the first color chip, the second color chip, and the third color chip has a bottom, and all the bottoms are mutually parallel.

To achieve the objectives and to address the technical issues of the present invention, the following technical scheme is also adopted. According to the present invention, a multi-field arranging method of LED chips under a single lens comprises the steps of: setting a first concentric circle on a bottom of a hemispherical lens wherein the first concentric circle is centered at an axis of the hemispherical lens; equidistantly arranging a plurality of first color chips, which are at least three said first color chips, on the first concentric circle; setting a second concentric circle on the bottom of the hemispherical lens wherein the second concentric circle is centered at the axis of the hemispherical lens and the second concentric circle is greater than the first concentric circle in radius; and arranging a plurality of second color chips and a plurality of third color chips, which are at least three said second color chip and at least three said third color chips on the second concentric circle, wherein the second color chips and the third color chips are alternately and equidistantly arranged on the second concentric circle.

To further achieve the objectives and to further address the technical issues of the present invention, the following technical measures may also be implemented.

In the foregoing multi-field arranging method, the first color chips, the second color chips and the third color chips are a plurality of red chips, a plurality of green chips, and a plurality of blue chips, respectively.

In the foregoing multi-field arranging method, the first color chips are arranged into an equilateral triangle.

In the foregoing multi-field arranging method, each of the first color chips, the second color chips, and the third color chips has a bottom, and all the bottoms are mutually parallel.

In the foregoing multi-field arranging method, one of first imaginary lines, which is links between the center of the second concentric circle and the center of one second color chip, has an included angle of 40° with one of second imaginary lines, which links between the center of the second concentric circle and the center of one third color chip anticlockwise adjacent to said second color chip, while one of the first imaginary lines has an included angle of 80° with one of third imaginary lines, which links between the center of the second concentric circle and the center of one third color chip clockwise adjacent to said second color chip.

To achieve the objectives and to address the technical issues of the present invention, the following technical scheme is also adopted. According to the present invention, a multi-field arranging method of LED chips under a single lens comprises the steps of: setting a first color chip on an axis of a hemispherical lens; setting a first concentric circle on a bottom of the hemispherical lens wherein the first concentric circle is centered at the first color chip; and arranging a plurality of second color chips and a plurality of third color chips, which are at least three said second color chips and at least three said third color chips, respectively, on the first concentric circle, wherein the second color chips and the third color chips are alternately and equidistantly arranged on the first concentric circle.

To further achieve the objectives and to further address the technical issues of the present invention, the following technical measures may be also implemented.

In the foregoing multi-field arranging method, the first color chip, the second color chips, and the third color chips are a red chip, a plurality of green chips, and a plurality of blue chips, respectively.

In the foregoing multi-field arranging method, the first color chip, the second color chips, and the third color chips are a green chip, a plurality of red chips, and a plurality of blue chips, respectively.

In the foregoing multi-field arranging method, the first color chip, the second color chips, and the third color chips are a blue chip, a plurality of red chips, and a plurality of green chips, respectively.

In the foregoing multi-field arranging method, each of the first color chip, the second color chips, and the third color chips has a bottom, and all the bottoms are mutually parallel, respectively.

As compared with prior art, the present invention has obvious benefits and profitable effects. It is learned from the foregoing technical schemes that the major technical contents of the present invention are as follows:

To achieve the aforementioned objectives, the present invention provides a multi-field arranging method of LED chips under a single lens, which comprises the steps of: setting a first concentric circle on a bottom of a hemispherical lens wherein the first concentric circle is centered at an axis of the hemispherical lens; and equidistantly arranging at least one first color chip, at least one second color chip and at least one third color chip on the first concentric circle in sequence.

In addition, to achieve the aforementioned objectives, the present invention further provides a multi-field arranging method of LED chips under a single lens comprises the steps of: setting a first concentric circle on a bottom of a hemispherical lens wherein the first concentric circle is centered at an axis of the hemispherical lens; equidistantly arranging a plurality of first color chips, which are at least three said first color chips, on the first concentric circle; setting a second concentric circle on the bottom of the hemispherical lens wherein the second concentric circle is centered at the axis of the hemispherical lens and the second concentric circle is greater than the first concentric circle in radius; and arranging a plurality of second color chips and a plurality of third color chips, which are at least three said second color chip and at least three said third color chips on the second concentric circle, wherein the second color chips and the third color chips are alternately and equidistantly arranged on the second concentric circle.

Moreover, to achieve the aforementioned objectives, the present invention further provides a multi-field arranging method of LED chips under a single lens comprises the steps of: setting a first color chip on an axis of a hemispherical lens; setting a first concentric circle on a bottom of the hemispherical lens wherein the first concentric circle is centered at the first color chip; and arranging a plurality of second color chips and a plurality of third color chips, which are at least three said second color chips and at least three said third color chips, respectively, wherein the second color chips and the third color chips are alternately and equidistantly arranged on the first concentric circle.

As compared with prior art, the present invention has obvious benefits and profitable effects. With the above technical schemes, the multi-field arranging method of the present invention at least has the following benefits and profitable effects:

The multi-field arranging method, when applied to a single lens, allows each of LED chips of different colors to present a symmetrical light pattern through the lens.

Since each of LED chips of different colors is allowed to present the symmetrical light pattern, the resultant color mixture can be evener.

The multi-field arranging method helps to maximize the density of the LED chips and thereby downsize the overall configuration.

To sum up, the present invention relates to a multi-field arranging method of LED chips under a single lens, which comprises the steps of: setting a first concentric circle; and arranging at least one first color chip, at least one second color chip and at least one third color chip. The first concentric circle is centered at an axis of a hemispherical lens and formed on a bottom of the hemispherical lens. The color chips are equidistantly arranged in sequence on the first concentric circle, so that all the color chips are allowed to present a symmetrical light pattern under the hemispherical lens, thereby achieving a light field of an evener color mixture. The present invention possessing the above-recited advantageous and practical merits has made significant improvement in both process and function, so as to provide obvious progress to the related technology and produce useful and practical effects. The present invention, as compared with the known configurations of LED chips under a hemispherical lens, has enhanced, outstanding effects, thus being more practical and being exactly a novel, progressive and practical approach.

### BRIEF DESCRIPTION OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is a diagram showing light intensity profiles through a conventional hemispherical lens;

FIG. 2 is another diagram showing light intensity profiles through the conventional hemispherical lens;

FIG. 3 is a diagram showing light intensity profiles through a conventional planar lens;

FIG. 4A is a schematic drawing illustrating LED chips of three colors arranged under the conventional hemispherical lens;

FIG. 4B shows the light pattern of the red LED chip under the conventional hemispherical lens;

FIG. 4C shows the light pattern of the green LED chip under the conventional hemispherical lens;

FIG. 4D shows the light pattern of the blue LED chip under the conventional hemispherical lens;

FIG. 5 is a flowchart of a multi-field arranging method of LED chips under a single lens according to a first preferred embodiment of the present invention;

FIG. 6 is an exploded view of the LED chips under the single lens according to FIG. 5;

FIG. 7 is a first exemplificative arrangement of the LED chips according to the preferred embodiment;

FIG. 8A is a perspective view of FIG. 7;

FIG. 8B shows a light pattern of the red LED chip of FIG. 7;

FIG. 8C is a diagram showing a light intensity profile of the red LED chip from a viewpoint along Arrow A of FIG. 8A;

FIG. 8D is a diagram showing a light intensity profile of the red LED chip from a viewpoint along Arrow B of FIG. 8A;

FIG. 9 is a second exemplificative arrangement of the LED chips according to the preferred embodiment;

FIG. 10 is a flowchart of a multi-field arranging method of LED chips under a single lens according to a second preferred embodiment of the present invention;

FIG. 11 is an exploded view of the LED chips under the single lens according to FIG. 10;

FIG. 12 is a third exemplificative arrangement of the LED chips according to the preferred embodiment;

FIG. 13 is a fourth exemplificative arrangement of the LED chips according to the preferred embodiment;

FIG. 14 is a fifth exemplificative arrangement of the LED chips according to the preferred embodiment;

FIG. 15 is a flowchart of a multi-field arranging method of LED chips under a single lens according to a third preferred embodiment of the present invention;

FIG. 16 is an exploded view of the LED chips under the single lens according to FIG. 15; and

FIG. 17 is a sixth exemplificative arrangement of the LED chips according to the preferred embodiment.

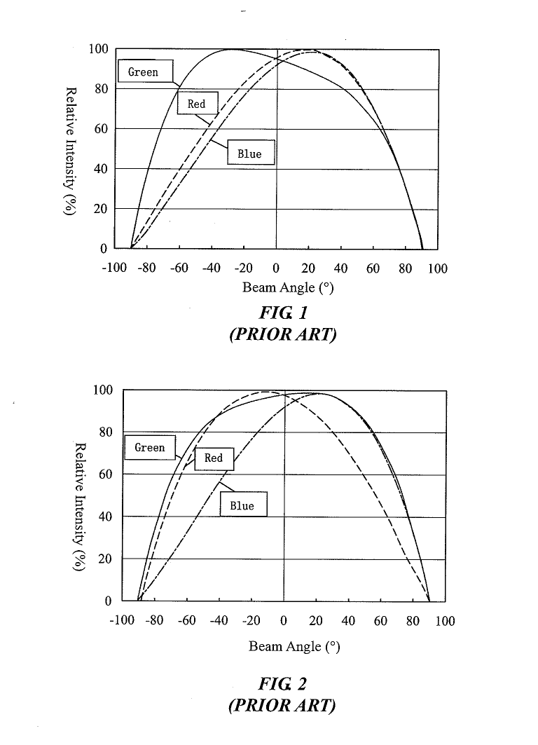

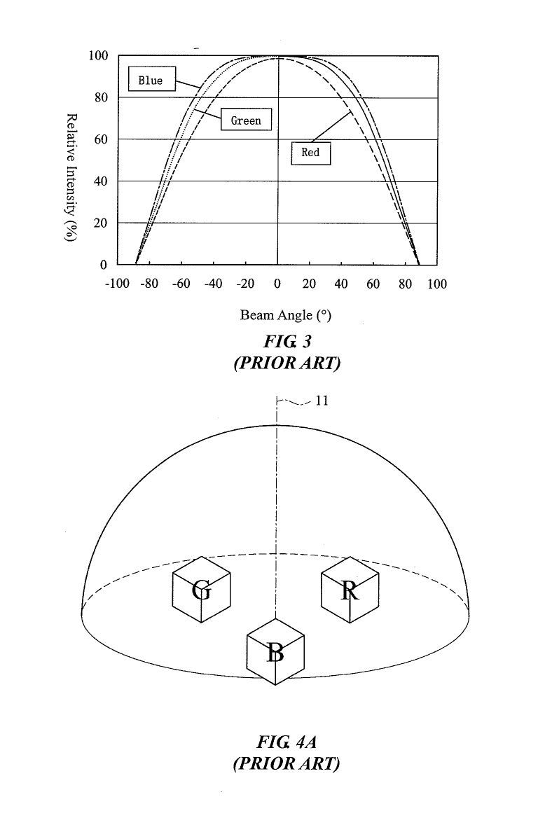

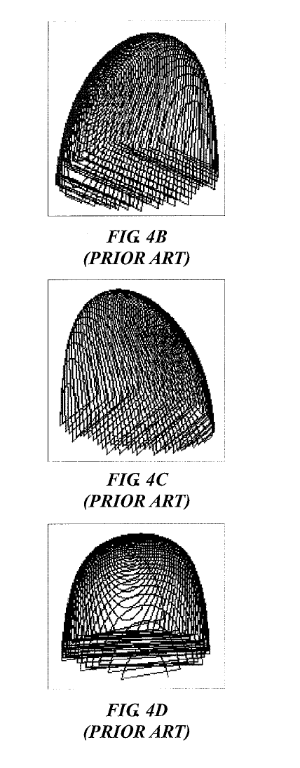

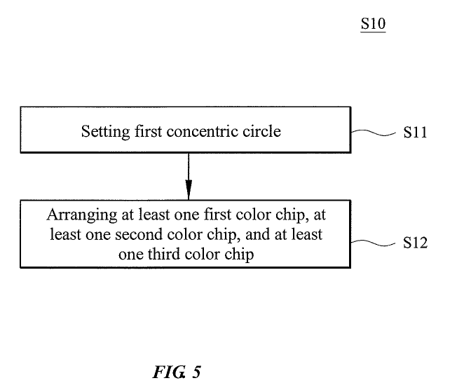

### DETAILED DESCRIPTION OF THE INVENTION

In order to further illustrate the technical means and effects the present invention adopts for achieving the foregoing objectives, with combination of the accompanying drawings and some preferred embodiments, the specific implementing means, manufacturing method, steps, features as well as the effects of the multi-field arranging method of LED chips under a single lens proposed by the present invention will be described in detail below.

The foregoing and other technical contents, features and effects of present invention, will be illustrated in detail below by some preferred embodiments together with the accompanying drawing. Through the detailed description of the invention, people skilled in the art would further and better understand the technical means adopted by the present invention to achieve the specific objectives and the effects of the present invention. However, the accompanying drawings are for the purposes of reference and illustration and shall form no limitation to the present invention.

### First Embodiment

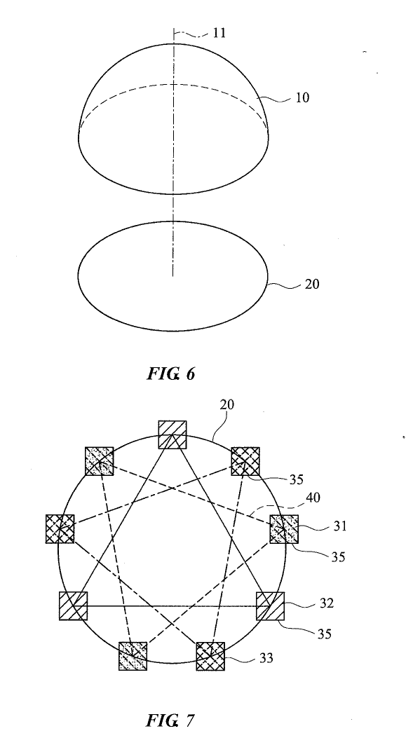

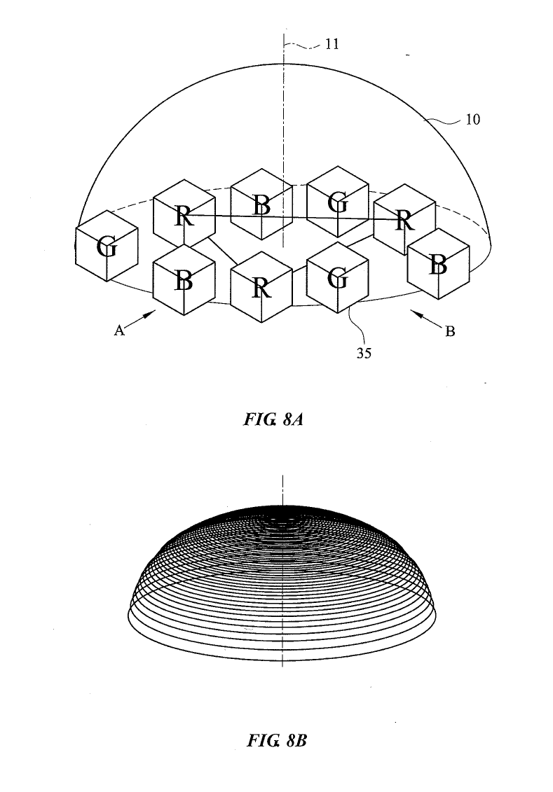

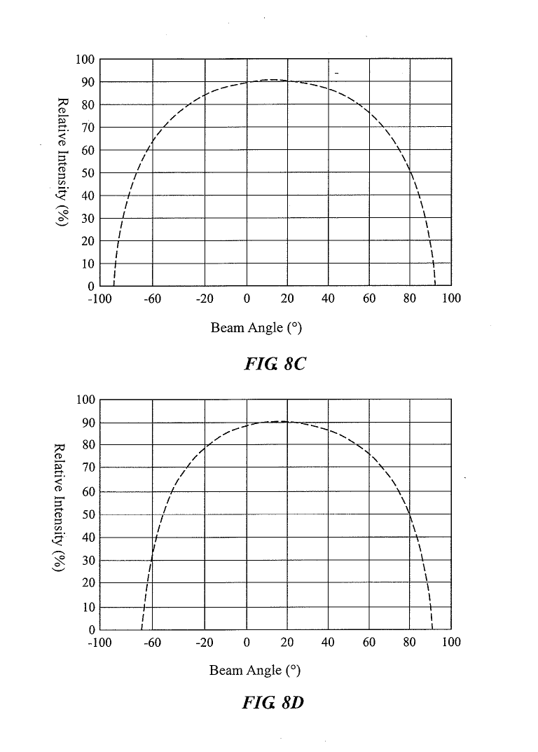

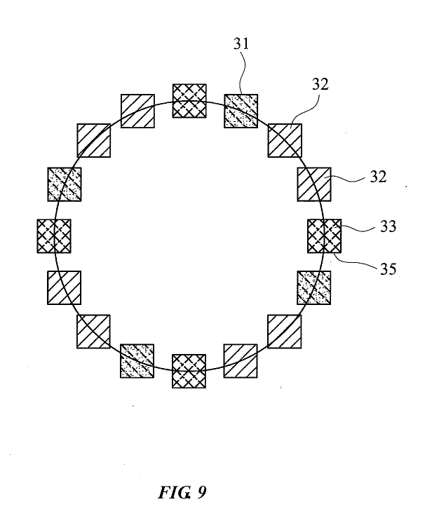

FIG. 5 is a flowchart of a multi-field arranging method S10 of LED chips under a single lens according to a first preferred embodiment of the present invention. FIG. 6 is an exploded view of the LED chips under the single lens according to FIG. 5. FIG. 7 is a first exemplificative arrangement of the LED chips according to the preferred embodiment. FIG. 8A is a perspective view of FIG. 7. FIG. 8B shows a light pattern of the red LED chip of FIG. 7. FIG. 8C is a diagram showing a light intensity profile of the red LED chip from a viewpoint along Arrow A of FIG. 8A. FIG. 8D is a diagram showing a light intensity profile of the red LED chip from a viewpoint along Arrow B of FIG. 8A. FIG. 9 is a second exemplificative arrangement of the LED chips according to the preferred embodiment.

Referring to FIG. 5, the multi-field arranging method S10 according to the first preferred embodiment of the present invention, comprises the steps of: setting a first concentric circle S11; and equidistantly arranging at least one first color chip, at least one second color chip, and at least one third color chip S12.

In the step of setting the first concentric circle S11, referring to FIG. 6, the single lens may be a hemispherical lens 10, and the first concentric circle 20 is formed on a bottom of the hemispherical lens 10, wherein the first concentric circle 20 is centered at an axis 11 of the hemispherical lens 10.

In the step of arranging at least one first color chip, at least one second color chip, and at least one third color chip S12, referring to FIG. 7, three first color chips 31, three second color chips 32, and three third color chips 33 are arranged on the first concentric circle 20 alternately and equidistantly in sequence. The first color chips 31, the second color chips 32, and the third color chips 33 are composed of red chips, green chips, and blue chips. Each set of the three sequent first color chip 31, second color chip 32, and third color chip 33 are arranged in an order of red, green, and blue, and all of the chips 31, 32, 33 of the same colors may form an equilateral triangle 40. The red chip has a light wavelength ranging between 630 and 780 nm, and the green chip has a light wavelength ranging between 500 and 570 nm, while the blue chip has a light wavelength ranging between 420 and 470 nm.

Since the color chips 31, 32, 33 are arranged alternately and equidistantly on the first concentric circle 20 in sequence, optical axes of all the color chips 31, 32, 33 are equidistant from the axis 11. In addition, the optical axes of the chips 31, 32 or 33 of the same color are equidistant and symmetrical with respect to each other. Therefore, in the event that the axis 11 of the hemispherical lens 10 is inconsistent with the optical axes of the chips 31, 32, and 33, the chips 31, 32 or 33 of the same color compensate mutually, thereby ensuring the chips 31, 32 or 33 of each color give a symmetrical light pattern.

For example, referring to FIG. 8A, there is a computer simulation of multiple chips 31, 32, and 33 arranged under the hemispherical lens 10 according to FIG. 7. The light pattern of any color of the color chips 31, 32, 33, such as the red chips, is symmetrical, as shown in FIG. 8B. Meantime, the light pattern of the chips 31, 32 or 33 of each color is consistent in any of observation viewpoints.

Referring to FIG. 8C and FIG. 8D, from the different viewpoints along Arrow A and Arrow B, the light patterns (or the light intensity profile) of the red chips are symmetrical. This shows that from different viewpoints, the observed light patterns of the chips 31, 32, and 33 are all symmetrical. As a result, each of the color chips 31, 32, 33 under the hemispherical lens 10 can present symmetrical light pattern from any viewpoint, so that even color mixture can be achieved. Referring to FIG. 9, in the multi-field arranging method S10, the LED chips may be chip sets composed of a first color chip 31, two second color chips 32, and a third color chip 33. A plurality of chip sets are equidistantly arranged on the first concentric circle 20 in sequence and in each said chip set, the first color chip 31, the second color chips 32, and the third color chip 33 may be arranged in an order of red, green, green, and blue.

Additionally, each of the first color chip 31, the second color chips 32, and the third color chips 33 has a bottom 35, which refers one lateral side of the chips 31, 32, and 33, and when the chips 31, 32, and 33 are arranged on the first concentric circle 20, all of the bottoms thereof are mutually parallel.

### Second Embodiment

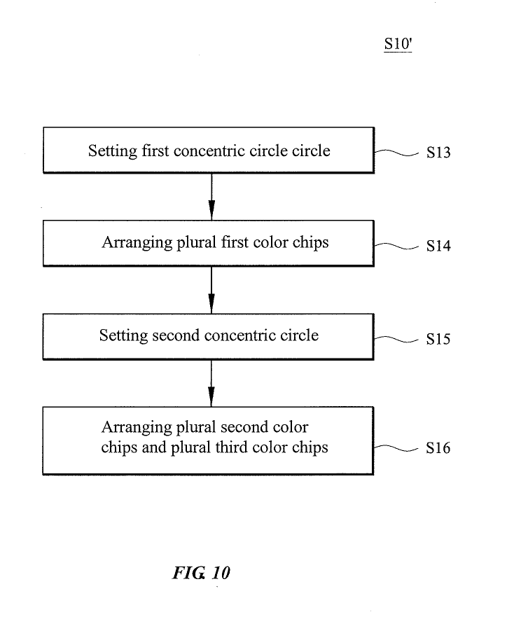

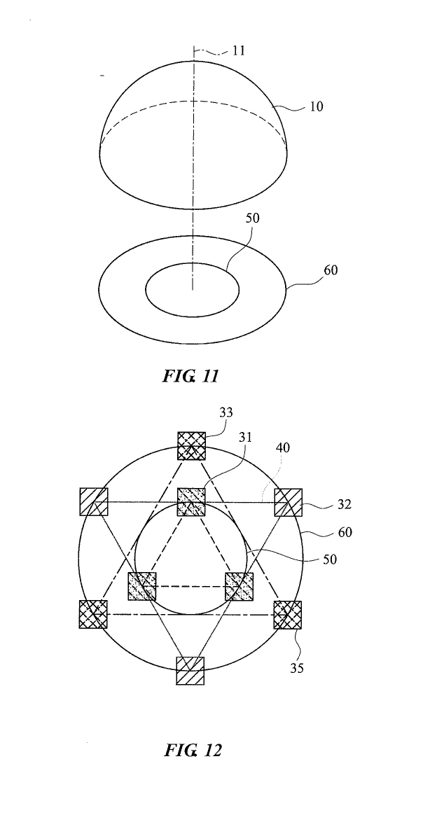

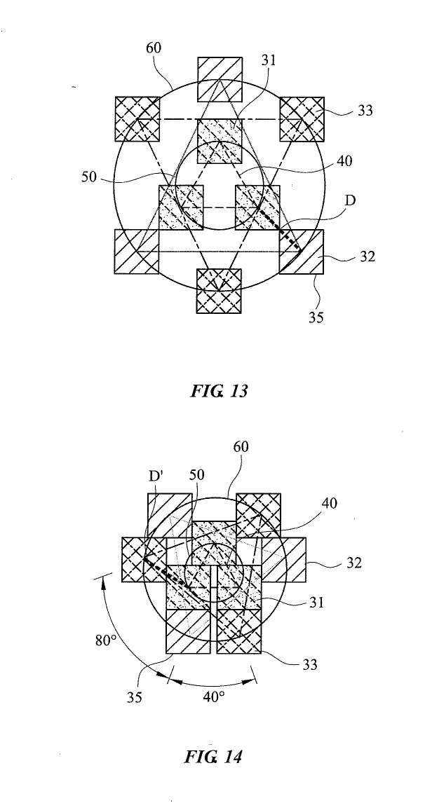

FIG. 10 is a flowchart of a multi-field arranging method S10′ of LED chips under a single lens according to a second preferred embodiment of the present invention. FIG. 11 is an exploded view of the LED chips under the single lens according to FIG. 10. FIG. 12 is a third exemplificative arrangement of the LED chips according to the preferred embodiment. FIG. 13 is a fourth exemplificative arrangement of the LED chips according to the preferred embodiment. FIG. 14 is a fifth exemplificative arrangement of the LED chips according to the preferred embodiment.

Referring to FIG. 10, the multi-field arranging method S10′ of the present invention comprises the steps of: setting a first concentric circle S13; arranging a plurality of first color chips S14; setting a second concentric circle S15; and arranging a plurality of second color chips and a plurality of third color chips S16.

In the step of setting a first concentric circle S13, referring to FIG. 11, the first concentric circle 50 is formed on a bottom of a hemispherical lens 10 and centered at an axis 11 of the hemispherical lens 10.

In the step of arranging a plurality of first color chips S14, referring to FIG. 12, at least three first color chips 31 are equidistantly arranged on the first concentric circle 50. The three first color chips 31 may be arranged into an equilateral triangle 40.

In the step of setting a second concentric circle S15, referring to FIG. 11 and FIG. 12, the second concentric circle 60 is also formed on the bottom of the hemispherical lens 10, and also centered at the axis 11 of the hemispherical lens 10. The second concentric circle 60 is larger than the first concentric circle 50 in radius. In other words, the second concentric circle 60 is formed to circle the first concentric circle 50.

In the step of arranging a plurality of second color chips and a plurality of third color chips S16, referring to FIG. 12, at least three second color chips 32 and at least three third color chips 33 are arranged on the second concentric circle 60 alternately and equidistantly.

The second color chips 32 and the third color chips 33 on the second concentric circle 60 may be connected to the first color chips 31 on the first concentric circle 50, so as to reduce the interval between adjacent color chips 31, 32, and 33, and thereby downsize the overall configuration. For example, referring to FIG. 13, the second color chips 32 on the second concentric circle 60 may be connected to the first color chips 31 on the first concentric circle 50. Since each of the color chips 31, 32, and 33 is a square, when the adjacent first color chip 31 and second color chip 32 are connected, a distance D between their centers is √2.

Referring to FIG. 14, the multi-field arranging method S10′ allows the arrangement of the maximum density, wherein one of first imaginary lines, which is links between the center of the second concentric circle 60 and the center of one second color chip 32, has an included angle of 40° with one of second imaginary lines, which links between the center of the second concentric circle 60 and the center of one third color chip 33 anticlockwise adjacent to said second color chip 32, while one of the first imaginary lines has an included angle of 80° with one of third imaginary lines, which links between the center of the second concentric circle 60 and the center of one third color chip 33 clockwise adjacent to said second color chip 32. At this time, the second color chips 32, and the third color chips 33 are connected to the first color chips 31, and a distance D′ between any of the second color chips and the adjacent first color chip 31 or between any of the third color chips and the adjacent first color chip 31 is smaller than √2, thereby achieving the arrangement of the maximum density.

In addition, the first color chips 31, the second color chips 32, and the third color chips 33 may be composed of red chips, green chips, and blue chips. Each of the first color chips 31, the second color chips 32, and the third color chips 33 has a bottom 35. When respectively arranged on the first concentric circle 50 and the second concentric circle 60, all the color chips 31, 32, and 33 have their bottoms 35 mutually parallel.

Since the multi-field arranging method S10′ arranges the LED chips equidistantly, when three of the second color chips 32 and three of the third color chips 33 are provided on the second concentric circle 60, the chip 31, 32 or 33 of each color may form an equilateral triangle 40. Meantime, each of the first color chips 31, the second color chips 32, and the third color chips 33 has a bottom 35. When arranged on the first concentric circle 20, the color chips 31, 32, and 33 have their bottom 35 mutually parallel.

By using the multi-field arranging method S10′, the plural chips 31, 32, and 33 can be arranged as close as possible, so the overall configuration can be downsized. In addition, since the color chips 31, 32 or 33 of each color are formed into the equilateral triangle 40, the chips 31, 32 or 33 of the same color can have their light patterns compensate mutually so that the light pattern of each of the colors is symmetrical, thereby improving color mixture at the peripheral portion of the hemispherical lens 10.

### Third Embodiment

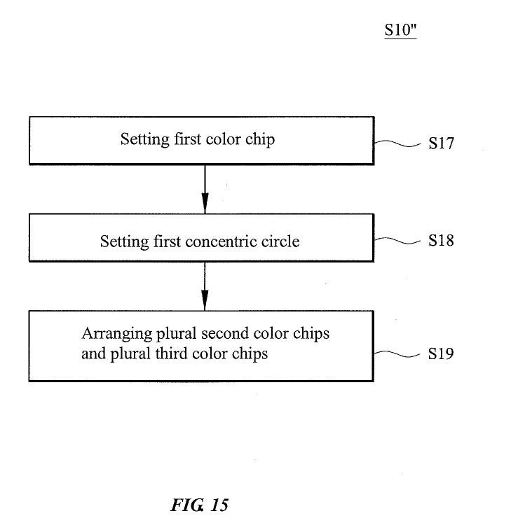

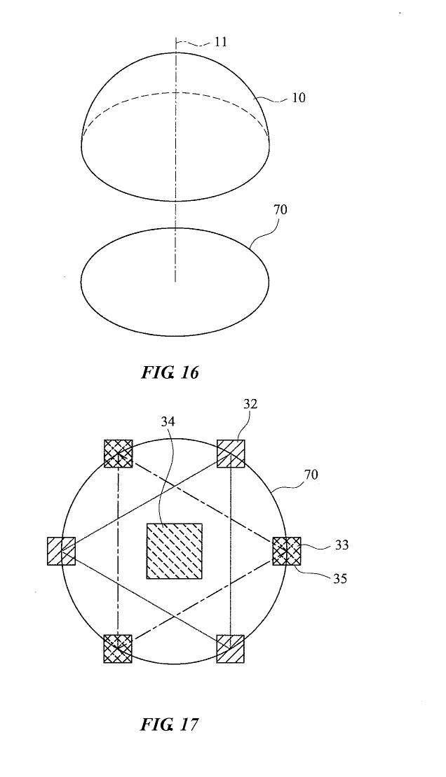

FIG. 15 is a flowchart of a multi-field arranging method S10″ of LED chips under a single lens according to a third preferred embodiment of the present invention. FIG. 16 is an exploded view of the LED chips under the single lens according to FIG. 15. FIG. 17 is a sixth exemplificative arrangement of the LED chips according to the preferred embodiment.

Referring to FIG. 15, the multi-field arranging method S10″ of the present invention comprises the steps of: setting a first color chip S17; setting a first concentric circle S18; and arranging a plurality of second color chips and a plurality of third color chips S19.

In the step of arranging the first color chip S17, referring to FIG. 16, the first color chip 34 is formed on an axis 11 of a hemispherical lens 10. The first color chip 34 may be an LED chip with a relatively large size.

In the step of setting the first concentric circle S18, referring to FIG. 17, the first concentric circle 70 is formed on a bottom of the hemispherical lens 10, and the first concentric circle 70 is centered at the first color chip 34.

In the step of arranging a plurality of second color chips and a plurality of third color chips S19, referring to FIG. 17, at least three second color chips 32 and at least three third color chips 33 are provided on the concentric circle 70 alternately and equidistantly.

The composition of the first color chip 34, the second color chips 32, and the third color chips 33 may be realized through any of the following examples. When the first color chip 34 is a red chip, the second color chips 32 and third color chips 33 may be composed of a plurality of green chips and a plurality of blue chips. When the first color chip 34 is a green chip, the second color chips 32 and the third color chips 33 may be composed of a plurality of red chips and a plurality of blue chips. Alternatively, when the first color chip 34 is a blue chip, the second color chips 32 and third color chips 33 may be composed of a plurality of green chips and a plurality of red chips.

In addition, each of the first color chip 34, the second color chips 32, and the third color chips 33 has a bottom 35. When arranged on the first concentric circle 70, respectively, the color chips have their bottoms 35 mutually parallel. When three of the second color chips 32 and three of the third color chips 33 are arranged on the first concentric circle 70, each three chips 32 or 33 of the same color may form an equilateral triangle 40, so that the chips 32 or 33 of the same color can have the light patterns compensate mutually to present a symmetrical resultant light pattern of the color, thereby achieving even color mixture through the hemispherical lens 10. The multi-field arranging method S10″ adopts concentric circle arrangements of the LED chips, so as to arrange the plural chips 32, 33 as close as possible, thereby downsizing the overall configuration.

Instead of red chips, green chips, and blue chip, the foregoing first color chips 31, second color chips 32, and third color chips 33 may be chips of the same color additionally applied with fluorescent powder, such as blue chips applied with yellow fluorescent powder.

Moreover, by adjusting the light intensity of the chips 31, 32, and 33 and using fluorescent powder of different color, the final color temperature and light intensity after color mixture can be modified. The light after color mixture adjusted by fluorescent powder may present a warm hue or a cold hue. For example: blue chips and yellow fluorescent powder after color mixture can produce white light. By further using red fluorescent powder, the white light may be adjusted to warm white light.

For enhancing the color rendering index (CRI) of color mixture, a chip 31, 32 or 33 with a relatively small size may be arranged under the hemispherical lens 10. For example, a red chip with a relatively small size may be provided to enhance the CRI to red objects.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A multi-field arranging method of LED chips under a single lens, the method comprising steps of:
setting a first concentric circle on a bottom of a hemispherical lens, wherein the first concentric circle is centered at an axis of the hemispherical lens; and
equidistantly arranging at least one first color chip, at least one second color chip and at least one third color chip on the first concentric circle in sequence.

2. The multi-field arranging method of claim 1, wherein the first color chip, the second color chip, and the third color chip are composed of a red chip, a green chip, and a blue chip, respectively.

3. The multi-field arranging method of claim 2, wherein the chips are arranged in an order of red, green, and blue.

4. The multi-field arranging method of claim 1, comprising one said first color chip, two said second color chips, and one said third color chip.

5. The multi-field arranging method of claim 4, wherein the color chips are arranged in an order of red, green, green, and blue.

6. The multi-field arranging method of claim 1, wherein each of the first color chip, the second color chip, and the third color chip has a bottom, and all of the bottoms are mutually parallel.

7. A multi-field arranging method of LED chips under a single lens, the method comprising steps of:
setting a first concentric circle on a bottom of a hemispherical lens, wherein the first concentric circle is centered at an axis of the hemispherical lens;
arranging a plurality of first color chips, which are at least three said first color chip, on the first concentric circle, wherein the first color chips are arranged equidistantly;
setting a second concentric circle on the bottom of the hemispherical lens, wherein the second concentric circle is centered at the axis of the hemispherical lens, and the second concentric circle is larger than the first concentric circle in radius; and
arranging a plurality of second color chips and a plurality of third color chips, which are at least three said second color chips and at least three said third color chips, respectively, wherein the second color chips and the third color chips are alternately and equidistantly arranged on the second concentric circle.

8. The multi-field arranging method of claim 7, wherein the first color chips, the second color chips, and the third color chips are composed of a plurality of red chips, a plurality of green chips, and a plurality of blue chips, respectively.

9. The multi-field arranging method of claim 7, wherein the first color chips are arranged into an equilateral triangle.

10. The multi-field arranging method of claim 7, wherein each of the first color chips, the second color chips, and the third color chips has a bottom, and all of the bottoms are mutually parallel.

11. The multi-field arranging method of claim 7, wherein one of first imaginary lines, which is links between a center of the second concentric circle and a center of one said second color chip, has an included angle of 40° with one of second imaginary lines, which links between the center of the second concentric circle and a center of one said third color chip anticlockwise adjacent to said second color chip, while one of the first imaginary lines has an included angle of 80° with one of third imaginary lines, which links between the center of the second concentric circle and the center of one said third color chip clockwise adjacent to said second color chip.

12. A multi-field arranging method of LED chips under a single lens, the method comprising steps of:
setting a first color chip on an axis of a hemispherical lens;
setting a first concentric circle on a bottom of the hemispherical lens, wherein the first concentric circle is centered at the first color chip; and
arranging a plurality of second color chips and a plurality of third color chips, which are at least three said second color chip and at least three said third color chip, respectively, wherein the second color chips and the third color chips are alternately and equidistantly arranged on the first concentric circle.

13. The multi-field arranging method of claim 12, wherein the first color chip, the second color chips, and the third color chips are composed of a red chip, a plurality of green chips, and a plurality of blue chips, respectively.

14. The multi-field arranging method of claim 12, wherein the first color chip, the second color chips, and the third color chips are composed of a green chip, a plurality of red chips, and a plurality of blue chips, respectively.

15. The multi-field arranging method of claim 12, wherein the first color chip, the second color chips, and the third color chips are composed of a blue chip, a plurality of red chips, and a plurality of green chips, respectively.

16. The multi-field arranging method of claim 12, wherein each of the first color chip, the second color chips, and the third color chips has a bottom, and all of the bottoms are mutually parallel.
